(19) United States
(12) Patent Application Publication
(10) Pub. No.: US 2014/0167737 A1
(43) Pub. Date: Jun. 19, 2014

(54) AC DETECTION CIRCUIT AND OPERATING METHOD THEREOF

(71) Applicant: SAMSUNG ELECTRO-MECHANICS CO., LTD., Suwon (KR)

(72) Inventors: Sung Hun OH, Suwon (KR); Won Young LEE, Suwon (KR); Hyo Young KIM, Suwon (KR)

(21) Appl. No.: 13/915,397

(22) Filed: Jun. 11, 2013

(30) Foreign Application Priority Data
Dec. 18, 2012 (KR) 10-2012-0148254

(51) Int. Cl. G01R 1/30

(52) U.S. Cl. CPC G01R 1/30
USPC 324/119

(57) ABSTRACT

There are provided an alternating current (AC) detection circuit and an operating method thereof. The AC detection circuit includes: a power supply unit outputting an AC signal; a filter unit connected to the power supply unit to block a serial signal component; and a detection circuit unit including at least one switching element turned on or turned off according to an output signal from the filter unit, and detecting whether the AC input signal has been input according to an operation of the at least one switching element.

### CROSS-REFERENCE TO RELATED APPLICATIONS

This application claims the priority of Korean Patent Application No. 10-2012-0148254 filed on Dec. 18, 2012, in the Korean Intellectual Property Office, the disclosure of which is incorporated herein by reference.

### BACKGROUND OF THE INVENTION

1. Field of the Invention

The present invention relates to an alternating current (AC) detection circuit in which a filter unit for blocking a direct current (DC) component is disposed between an AC power supply unit outputting an AC signal and a circuit for detecting whether an AC signal has been input, thereby improving a response speed, and an operating method thereof.

2. Description of the Related Art

An alternating current (AC) detection circuit is a circuit for generating output signals having different levels when an AC voltage is applied to a switched-mode power supply (SMPS) and when an application of the AC voltage is blocked. The AC detection circuit may be configured to generate an output signal having a high level when an AC voltage is applied normally, and generate an output signal having a low level when an AC voltage is blocked, and when the AC voltage is blocked, a main circuit connected to a rear stage of the AC detection circuit may stop operating according to the output signal having a low level from the AC detection circuit.

The AC detection circuit is required to quickly detect an application and block an AC voltage and immediately reflect the detection result in an output signal. In the case that an AC voltage, while being normally applied, is abruptly blocked, if an output signal from the AC detection circuit is not immediately changed to have a low level due to a slow response speed, an abnormal driving voltage is applied to the main circuit connected to a rear stage of the AC detection circuit, shortening a lifespan of the main circuit or damaging the main circuit.

In a generally used AC detection circuit, a relatively long time may be required for an AC detection signal to be changed to have a low level when an AC voltage is blocked, so in order to improve this problem, a method of using a voltage IC has been proposed. The use of a voltage IC can improve a response speed of the AC detection circuit, solving the problem of the abnormal driving voltage applied to the main circuit, but may increase manufacturing costs of the AC detection circuit.

Cited invention 1 below relates to an AC detection circuit for a power supply apparatus in which a voltage of an AC signal is compared with a reference voltage and an output signal having a duty ratio determined according to the comparison result is generated. Cited invention 2 relates to a power supply apparatus having a capacitor anti-explosion and phase detection function, in which a DC voltage is blocked with a smoothing capacitor. However, neither of cited inventions 1 and 2 disclose a configuration of improving a response speed of an overall circuit by excluding an influence of a DC component on the generation of an AC detection signal.

### RELATED ART DOCUMENT

(Patent document 1) Korean Patent Laid Open Publication No. 10-2011-0006792

(Patent document 2) Korean Patent Laid Open Publication No. 10-2005-0054509

### SUMMARY OF THE INVENTION

An aspect of the present invention provides an alternating current (AC) detection circuit having a fast response speed relative to an existing AC detection circuit without using a voltage IC, or the like, incurring high manufacturing costs, by disposing an element for filtering a DC component in a rear stage of a rectifying unit rectifying an AC signal and controlling turning-on and turning-off operations of a switching element included in a detection circuit unit with a DC component-filtered signal.

According to an aspect of the present invention, there is provided an alternating current (AC) detection circuit including: a power supply unit outputting an AC signal; a filter unit connected to the power supply unit to block a serial signal component; and a detection circuit unit including at least one switching element turned on or turned off according to an output signal from the filter unit, and detecting whether the AC input signal has been input according to an operation of the at least one switching element.

The AC detection circuit may further include: a rectifying unit connected between the power supply unit and the filter unit.

The AC detection circuit may further include: one or more resistors connected between the rectifying unit and the filter unit to divide the AC signal.

The filter unit may include one or more capacitors blocking the serial signal component.

The detection circuit unit may include: a first switching element turned on or turned off according to an output signal from the filter unit and a second switching element turned on or turned off by the first switching element to generate an output signal indicating whether the AC signal has been input.

The first switching element and the second switching element may include at least one of a bipolar junction transistor (BJT), a field effect transistor (FET), an operational amplifier, a comparator, and a shunt regulator.

When the first switching element is turned on, the second switching element may be turned off to generate an output signal having a low level, and when the first switching element is turned off, the second switch may be turned on to generate an output signal having a high level.

According to another aspect of the present invention, there is provided a method for operating an alternating current (AC) detection circuit, including: rectifying an AC signal; filtering a DC signal component included in the rectified AC signal; and generating an output signal indicating whether the AC signal has been input by controlling an operation of one or more switching elements by the filtered signal.

In the generating of an output signal, when the AC signal is input, the first switching element may be turned off by the filtered signal and the second switching element may be turned on by an output signal from the first switching element to generate an output signal having a low level.

In the generating of an output signal, when the AC signal is blocked, the first switching element may be turned on by the filtered signal and the second switching element may be turned off to generate an output signal having a high level.

According to another aspect of the present invention, there is provided an alternating current (AC) detection circuit including: a plurality of filtering elements connected to a live line and a neutral line of an AC power supply unit, respectively; a first switching element controlled to be turned on and turned off by filtering signals generated by the plurality of filtering elements; and a second switching element controlled to be turned on and turned off by an output signal from the first switching element, wherein when an AC signal is input from the AC power supply unit, the second switching element may generate an output signal having a high level, and when an AC signal from the AC power supply unit is blocked, the second switching element may generate an output signal having a low level.

A plurality of resistors may be connected between the live line and the neutral line of the AC power supply unit and the plurality of filtering elements, respectively.

The plurality of filtering elements may filter a DC component included in a signal transferred through the live line and the neutral line of the AC power supply unit.

When an AC signal is input from the AC power supply unit, the first switching element may be turned off and the second switching element may be turned on, and when the AC signal from the AC power supply unit is blocked, the first switching element may be turned on and the second switching element may be turned off.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of an alternating current (AC) detection circuit according to an embodiment of the present invention;

FIG. 2 is a circuit diagram illustrating an example of an AC detection circuit according to an embodiment of the present invention; and

FIG. 3 is a flow chart illustrating a method for operating an AC detection circuit according to an embodiment of the present invention.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

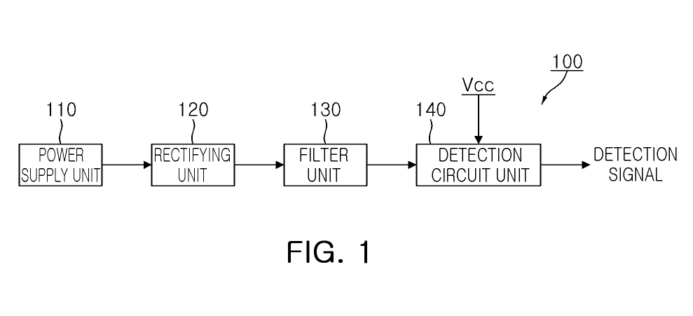

FIG. 1 is a schematic block diagram of an alternating current (AC) detection circuit according to an embodiment of the present invention.

Referring to FIG. 1, an AC detection circuit 100 according to an embodiment of the present invention may include a power supply unit 110, a rectifying unit 120, a filter unit 130, and a detection circuit unit 140. The power supply unit 110 may output AC power. The AC power output by the power supply unit 110 may be rectified by the rectifying unit 120 and transferred to the filter unit 130.

The rectifying unit 120 full-wave rectifies AC power. In order to rectify AC power, the rectifying unit 120 may include a diode. In an embodiment, two or more diodes may be included in the rectifying unit 120 in order to rectify AC power transmitted from a live line and a neutral line, respectively. The AC power full-wave rectified by the rectifying unit 129 is transferred to the filter unit 130.

The filter unit 130 may block a DC component included in the full-wave rectified AC power. A conventional general AC detection circuit does not include the filter unit 130 for filtering AC power full-wave rectified by the rectifying unit 120, and in most cases, a capacitor for simply performing smoothing is included. Thus, even though a signal having a DC component is transferred to the detection circuit unit 140 to block AC power from being inputted any further, the detection circuit unit 140 may determine that AC power is still being applied, a response speed is slowed, or the like.

In an embodiment of the present invention, the filter unit 130 is provided in an input terminal of the detection circuit unit 140, to solve the foregoing problem. In many cases, a capacitor, generally an X capacitor, is applied to an input terminal of AC power in order to prevent damage to a circuit due to static electricity. Thus, even when an input from an AC power source is blocked, the detection circuit unit 140 may malfunction because it recognizes that AC power is still being applied due to the presence of the charge charged in the capacitor for preventing static electricity. Also, due to a time required for the charges charged in the capacitor for preventing static electricity to be discharged, a response speed is degraded.

However, in an embodiment of the present invention, a DC component transferred to the input terminal of the detection circuit unit 140 is blocked by the filter unit 130 provided between the rectifying unit 120 and the detection circuit unit 140, reducing room for causing the foregoing problem. Namely, when AC power, being applied normally, is cut, a voltage that may be applied due to the charges remaining in the capacitor for preventing static electricity is blocked by the filter unit 130. Thus, when the AC power, being normally input, is blocked, the detection circuit unit 140 may quickly detect it to change a detection signal.

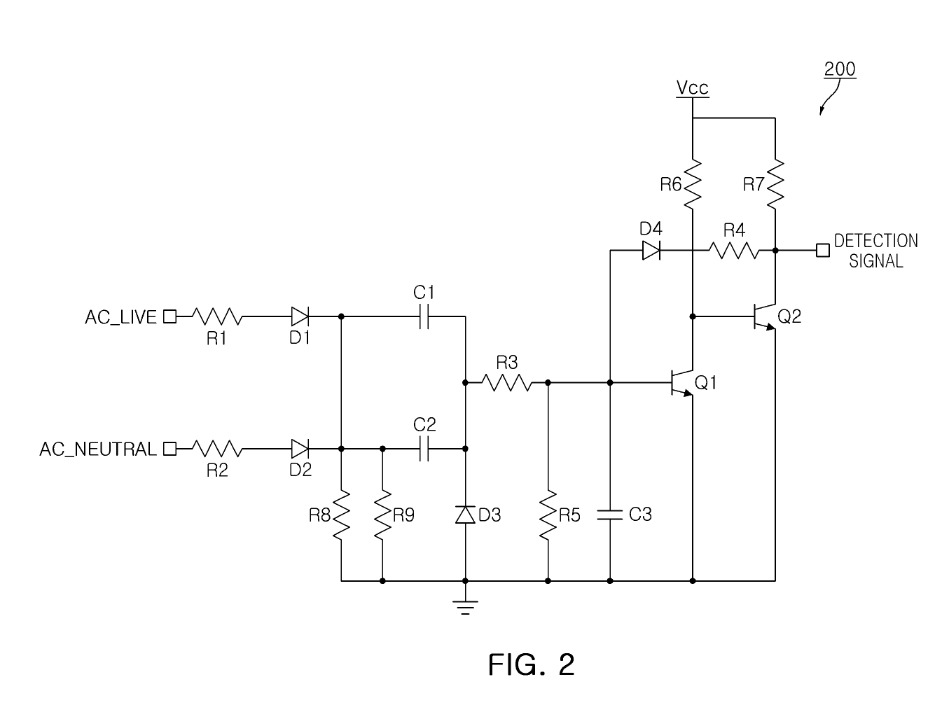

The detection circuit unit 140 generates a detection signal having a different level according to whether AC power is normally input. To this end, the detection circuit unit 140 may include one or more switching elements. Switching elements included in the detection circuit unit 140 may be a bipolar junction transistor (BJT), a field effect transistor (FET), an operational amplifier, a comparator, a shunt regulator, and the like. For example, when the detection circuit unit 140 includes a transistor such as BJT or FET as a switching element, a signal, which has passed through the filter unit 130, is transferred to a gate or gate terminal of the transistor to determine turn-on or turn-off of the switching element. Hereinafter, the AC detection circuit according to an embodiment of the present invention will be described in detail with reference to the circuit diagram of FIG. 2.

FIG. 2 is a circuit diagram illustrating an example of an AC detection circuit according to an embodiment of the present invention.

Referring to FIG. 2, AC power is transferred through a live line AC_LIVE and a neutral line AC_NEUTRAL, respectively. The AC power transferred through the active line and the neutral line passes through resistors R1 and R2 and is full-wave rectified by diodes D1 and D2 corresponding to the rectifying unit 120 of FIG. 1. The AC power full-wave rectified by the diodes D1 and D2 may be divided by resistors R8 and R9 so as to be input to capacitors C1 and C2 included in the filter unit 130.

The capacitors C1 and C2 correspond to the filter unit 130 of FIG. 1, and block a DC component included in the AC power full-wave rectified by the diodes D1 and D2. The AC power, which has passed through the capacitors C1 and C2, may be divided by resistors R3 and R5 so as to be transferred to a base terminal of a first switching element Q1.

As described above, the detection circuit unit 140 illustrated in FIG. 1 may include a plurality of switching elements for generating a detection signal indicating whether AC power has been input. In the circuit diagram of FIG. 2, BJTs Q1 and Q2 are illustrated as switching elements, but the present invention is not limited thereto and the detection circuit unit 140 may be configured to include an FET, an operational amplifier, a comparator, a shunt regulator, or the like, rather than the BJT.

When a voltage having a level sufficient for turning on the first switching element Q1 is applied to a base terminal of the first switching element Q1, the first switching element Q1 may be turned on and a voltage having a very low level may be applied to a base terminal of the second switching element Q2. Thus, the second switching element Q2 is turned off and a detection signal having a high level is output. Conversely, when a voltage having a low level is applied to the base terminal of the first switching element Q1 to turn off the first switching element Q1, the second switching element Q2 is turned on and a detection signal having a low level is output. This is shown together with signal levels of AC power in Table 1 below.

TABLE 1

| AC power | Normal input | Block |
|---|---|---|
| Q1 | Turn-on | Turn-off |
| Q2 | Turn-off | Turn-on |
| Detection signal | High level | Low level |

Namely, when AC power is normally input, a detection signal has a high level, and when AC power is blocked, a detection signal has a low level. Thus, when AC power, being normally applied, is suddenly blocked, the detection signal is required to be changed from a high level to a low level within a short time, and if the detection signal is not changed within a short time, it may be recognized that AC power is still being normally applied to result in an application of an abnormal voltage to a main circuit.

In an existing AC detection circuit without the capacitors C1 and c2 corresponding to the filter unit 130, when AC power, being applied, is blocked, a response speed is degraded due to the capacitor included in the AC power in order to prevent damage due to static electricity. Namely, although AC power is blocked, a voltage is continuously applied to the base terminal of the first switching element Q1 due to the charge charged in the X capacitor for preventing damage due to static electricity, so the first switching element Q1 is continuously turned on and the detection signal is still output to have a high level. As a result, an erroneous detection signal may be output until the charges charged in the X capacitor are wholly discharged or sufficiently discharged to turn off the first switching element Q1.

However, in an embodiment of the present invention, the capacitors C1 and C2 for filtering a DC component are disposed between the base terminal of the first switching element Q1 and the diodes D1 and D2 as rectifying elements, to solve the foregoing problem. Namely, in the case in which a voltage is transferred to the first switching element Q1 due to charges remaining in the X capacitor, the capacitors C1 and C2 block the voltage due to the charges remaining in the X capacitor, so the first switching element Q1 is immediately turned off when the AC power is blocked. When the AC power is blocked, the detection signal is changed from a high level to a low level within a short time, thus solving the problem in which an abnormal voltage is applied to the main circuit.

Meanwhile, the resistors R8 and R9 divide AC power from the input terminal. Thus, the resistors R3 and R5 connected a rear stage of the capacitors C1 and C2 may be configured as elements having a relatively small resistance value, respectively. Also, due to the presence of the capacitors C1 and C2, a smoothing capacitor can be eliminated from the AC detection circuit 200. Thus, unlike the general AC detection circuit, a time required for charges charged in the smoothing capacitor due to the smoothing capacitor and the resistors R3 and R5 having a high value, to be discharged can be reduced.

When AC power having a level having a broad range is applied, the first switching element Q1 is required to be turned on even with AC power having the lowest level. In this case, when AC power having the highest level, being applied, is blocked, a time required for the charges charged in the smoothing capacitor to be discharged is significantly lengthened as compared to the case in which AC power having the lowest level, being applied, is blocked. Thus, in an embodiment of the present invention, the capacitors C1 and C2 operating as the filter unit 130 are disposed, the smoothing capacitor is eliminated, and the resistors R3 and R5 are implemented as elements having a small value, respectively, whereby the AC detection circuit 200 stably operating over AC power having a broad level range can be implemented.

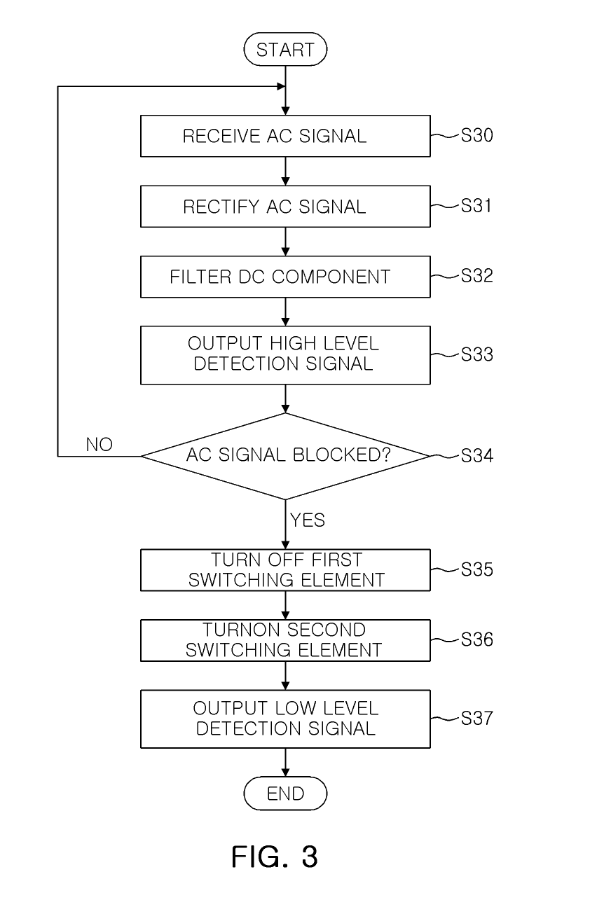

FIG. 3 is a flow chart illustrating a method for operating an AC detection circuit according to an embodiment of the present invention.

Referring to FIG. 3, a method for operating the AC detection circuit 200 according to the present embodiment starts with receiving an AC signal (S30). When the AC signal is received from the live line (AC_LIVE) and the neutral line (AC_NEUTRAL), the diodes D1 and D2, or the like, full-wave rectify the AC signal (S31), and the capacitors C1 and C2 filter a DC component included in the AC signal.

As discussed above, due to the presence of the capacitors C1 and C2 operating as filters with respect to a DC component, a response speed of the first switching element Q1 can be improved. By disposing the capacitors C1 and C2, a DC component due to charges charged in the X capacitor included in the power supply unit applying an AC signal can be blocked. Meanwhile, by dividing a voltage in the input terminal by connecting the resistors R8 and R9 to the input terminal, the resistors R3 and R5 may be implemented as elements having a small value and a smoothing capacitor can be eliminated. Thus, the problem in which a response speed of the first switching element Q1 is slowed due to a time required for the charges charged in the smoothing capacitor to be discharged can also be solved.

When a DC component-filtered AC signal is applied, the first switching element Q1 is turned on and the second switching element Q2 is turned off, so a detection signal having a high level is output (S33). When the normally applied AC signal is blocked (S34), the first switching element Q1 is turned off (S35) and the second switching element Q2 is turned on (S36). Thus, the detection signal output with a high level is changed to have a low level, and the main circuit stops an operation process.

When the AC signal is blocked, the capacitors C1 and C2 block a DC component due to charges charged in the X capacitor provided in the input terminal of the AC signal to allow the first switching element Q1 to be quickly turned off. Also, since a smoothing capacitor is eliminated due to the presence of the capacitors C1 and C2, the problem in which the first switching element Q1 is turned on while the charges charged in the smoothing capacitor is being discharged can be solved.

As set forth above, according to embodiments of the invention, a DC signal component included in a rectified AC signal is blocked by disposing the filter unit between the AC signal rectified by the rectifying unit and the detection circuit unit determining whether an AC signal has been input. Thus, when the AC signal input is blocked, an influence of the DC component remaining in an element included for preventing static electricity in the input terminal of the AC signal on the detection circuit unit is eliminated, so whether an AC signal has been input can be accurately and quickly detected.

While the present invention has been shown and described in connection with the embodiments, it will be apparent to those skilled in the art that modifications and variations can be made without departing from the spirit and scope of the invention as defined by the appended claims.

What is claimed is:

1. An alternating current (AC) detection circuit comprising:
a power supply unit outputting an AC signal;
a filter unit connected to the power supply unit to block a serial signal component; and
a detection circuit unit including at least one switching element turned on or turned off according to an output signal from the filter unit, and detecting whether the AC input signal has been input according to an operation of the at least one switching element.

2. The AC detection circuit of claim 1, further comprising: a rectifying unit connected between the power supply unit and the filter unit.

3. The detection circuit of claim 2, further comprising: one or more resistors connected between the rectifying unit and the filter unit to divide the AC signal.

4. The detection circuit of claim 1, wherein the filter unit comprises one or more capacitors blocking the serial signal component.

5. The detection circuit of claim 1, wherein the detection circuit unit comprises a first switching element turned on or turned off according to an output signal from the filter unit and a second switching element turned on or turned off by the first switching element to generate an output signal indicating whether the AC signal has been input.

6. The detection circuit of claim 5, wherein the first switching element and the second switching element include at least one of a bipolar junction transistor (BJT), a field effect transistor (FET), an operational amplifier, a comparator, and a shunt regulator.

7. The detection circuit of claim 5, wherein when the first switching element is turned on, the second switching element is turned off to generate an output signal having a low level, and
when the first switching element is turned off, the second switch is turned on to generate an output signal having a high level.

8. A method for operating an alternating current (AC) detection circuit, the method comprising:
rectifying an AC signal;
filtering a DC signal component included in the rectified AC signal; and
generating an output signal indicating whether the AC signal has been input by controlling an operation of one or more switching elements by the filtered signal.

9. The method of claim 8, wherein in the generating of an output signal, when the AC signal is input, the first switching element is turned off by the filtered signal and the second switching element is turned on by an output signal from the first switching element to generate an output signal having a low level.

10. The detection circuit of claim 8, wherein in the generating of an output signal, when the AC signal is blocked, the first switching element is turned on by the filtered signal and the second switching element is turned off to generate an output signal having a high level.

11. An alternating current (AC) detection circuit comprising:
a plurality of filtering elements connected to a live line and a neutral line of an AC power supply unit, respectively;
a first switching element controlled to be turned on and turned off by filtering signals generated by the plurality of filtering elements; and
a second switching element controlled to be turned on and turned off by an output signal from the first switching element,
wherein when an AC signal is input from the AC power supply unit, the second switching element generates an output signal having a high level, and when an AC signal from the AC power supply unit is blocked, the second switching element generates an output signal having a low level.

12. The AC detection circuit of claim 11, wherein a plurality of resistors are connected between the live line and the neutral line of the AC power supply unit and the plurality of filtering elements, respectively.

13. The AC detection circuit of claim 11, wherein the plurality of filtering elements filter a DC component included in a signal transferred through the live line and the neutral line of the AC power supply unit.

14. The AC detection circuit of claim 11, wherein when an AC signal is input from the AC power supply unit, the first switching element is turned off and the second switching element is turned on, and
when the AC signal from the AC power supply unit is blocked, the first switching element is turned on and the second switching element is turned off.
